(19) United States
(12) Patent Application Publication
(10) Pub. No.: US 2025/0364898 A1
(43) Pub. Date: Nov. 27, 2025

(54) POWER CONVERTOR AND CONTROL METHOD THEREOF FOR REDUCING REVERSE RECOVERY CHARGE OF LOW-SIDE TRANSISTOR

(71) Applicant: Richtek Technology Corporation, Zhubei City, Hsinchu County (TW)

(72) Inventors: Ta-Yung YANG, Taoyuan City (TW); Kuo-Chi LIU, Hsinchu City (TW)

(21) Appl. No.: 19/194,423

(22) Filed: Apr. 30, 2025

Related U.S. Application Data
(60) Provisional application No. 63/652,073, filed on May 27, 2024.

(30) Foreign Application Priority Data
Dec. 12, 2024 (TW) 113148363

(51) Int. Cl. H02M 1/088; H02M 3/158; H03K 17/687; H10D 84/00

(52) U.S. Cl. CPC H02M 1/088; H02M 3/158; H03K 17/687; H10D 84/154; H03K 2217/0063; H03K 2217/0072

(57) ABSTRACT

A power conversion circuit includes a high-side transistor, a low-side transistor, and a driving circuit. The high-side transistor provides an input voltage to a switch node based on a first signal. The low-side transistor couples the switch node to a ground based on a second signal, and is deposited in an isolation layer. The driving circuit generates the first signal, the second signal, and the third signal, provides a third signal to the isolation layer, and generates the third signal based on the first signal and the second signal.

### CROSS REFERENCE TO RELATED APPLICATIONS

This application claims the benefit of U.S. Provisional Application No. 63/652,073, filed on May 27, 2024, the entirety of which is incorporated by reference herein.

This application claims priority of Taiwan Patent Application No. 113148363, filed on Dec. 12, 2024, the entirety of which is incorporated by reference herein.

### BACKGROUND OF THE INVENTION

### Field of the Invention

The disclosure is generally related to a power convertor and a control method thereof, and more particularly it is related to a power convertor and a control method thereof for reducing the reverse recovery charge of a low-side transistor.

### Description of the Related Art

FIG. 1 is a schematic diagram showing a synchronous buck converter. As shown in FIG. 1, when the high-side transistor QH is turned on, the charge current IC generated by the input voltage VIN flows through the high-side transistor QH, the inductor L and the load LD to the ground. The output capacitor CO is configured to maintain the output voltage VO. When the high-side transistor QH is turned off and the low-side transistor QL is turned on, a discharge current ID flows through the low-side transistor QL, the inductor L, and the load LD from the ground. When the low-side transistor QL is turned off, the discharge current ID flows through the parasitic diode DP of the low-side transistor QL instead, so that many minority carriers are accumulated at the drain terminal and the base terminal of the low-side transistor QL as the stored charge. When the high-side transistor QH is turned on again, the minority carriers accumulated at the drain terminal and the base terminal of the low-side transistor QL must be removed, and the removal of the accumulated minority carriers is called reverse recovery charge.

In a switching power conversion circuit, the reverse recovery charge of the switching element has always been a killer of the power conversion circuit efficiency. In addition, since the reverse recovery charge cannot be reduced through circuit means, it has always been ignored. However, as the operating frequency of the power conversion circuit increases, the impact of reverse recovery charge on efficiency becomes increasingly serious and has become a problem that must be addressed.

### BRIEF SUMMARY OF THE INVENTION

The present invention proposes a power conversion circuit and a control method for reducing reverse recovery charge. The reverse recovery charge is reduced by placing a switch element in an isolation layer and reverse biasing a parasitic diode formed by the isolation layer before the switching element is turned off. In addition, the biasing of the isolation layer is stopped before the switch element is turned on to reduce the on-resistance of the switch element.

In an embodiment, a power conversion circuit comprises a high-side transistor, a low-side transistor, and a driving circuit. The high-side transistor provides an input voltage to a switch node based on a first signal. The low-side transistor couples the switch node to a ground based on a second signal and deposited in an isolation layer. The driving circuit generates the first signal, the second signal, and a third signal. The driving circuit provides the third signal to the isolation layer. The driving circuit generates the third signal based on the first signal and the second signal.

According to an embodiment of the present invention, before the low-side transistor is turned on, the driving circuit outputs the third signal at a low voltage level.

According to an embodiment of the present invention, before the low-side transistor is turned off, the driving circuit outputs the third signal at a high voltage level to reduce reverse recovery charge of the low-side transistor.

According to an embodiment of the present invention, the low-side transistor is an N-type laterally diffused metal oxide semiconductor.

According to an embodiment of the present invention, the high-side transistor is an N-type laterally diffused metal oxide semiconductor.

According to an embodiment of the present invention, the power conversion circuit is a synchronous buck converter.

According to an embodiment of the present invention, the low-side transistor comprises a semiconductor substrate, a barrier layer, a first well, a second well, a third well, a first doping region, a second doping region, a third doping region, a fourth doping region, a fifth doping region, and a gate structure. The semiconductor substrate has a first conductivity type. The barrier layer has a second conductivity type and is deposited on the semiconductor substrate. The first well has the second conductivity type, is deposited on the barrier layer, and is in contact with the barrier layer. The second well has the first conductivity type and is deposited in the first well. The third well has the second conductivity type and is deposited in the second well. The first doping region has the second conductivity type and is deposited in the first well. The second doping region has the first conductivity type and is deposited in the second well. The third doping region has the second conductivity type and is deposited in the third well. The fourth doping region has the first conductivity type and is deposited in the second well. The fifth doping region has the second conductivity type, is deposited in the second well, and is in contact with the fourth doping region. The gate structure is deposited on the second well and the third well and deposited between the fifth doping region and the third doping region. The barrier layer and the first well form the isolation layer. The first conductivity type and the second conductivity type are different.

According to an embodiment of the present invention, the low-side transistor comprises a gate terminal, a source terminal, a drain terminal, and a base terminal. The gate structure forms the gate terminal. The fourth doping region and the fifth doping region form the source terminal. The second doping region forms the drain terminal.

According to an embodiment of the present invention, the low-side transistor comprises a fourth well, a sixth doping region, a seventh doping region, a first isolation structure, a second isolation structure, a third isolation structure, and a fourth isolation structure. The fourth well has the first conductivity type surrounds the first well and is in contact with the semiconductor substrate. The sixth doping region has the first conductivity type and is deposited in the second well. The seventh doping region has the first conductivity type and is deposited in the fourth well. The first isolation structure is deposited between the first doping region and the seventh doping region. The second isolation structure is deposited between the first doping region and the second doping region. The third isolation structure is deposited between the second doping region and the third doping region. The fourth isolation structure is deposited between the fourth doping region and the sixth doping region. The sixth doping region forms the base terminal.

According to an embodiment of the present invention, the first doping region receives the third signal.

According to an embodiment of the present invention, when the first doping region receives the third signal being at a high voltage level and the low-side transistor is turned off, an interface between the first well and the second well and an interface between the barrier layer and the second well are reverse-biased, so as to reduce the minority carriers in the second well that need to be eliminated, thereby reducing reverse recovery charge.

According to an embodiment of the present invention, when the first doping region receives the third signal being at a low voltage level and the low-side transistor is turned on, the low-side transistor has low on-resistance.

According to an embodiment of the present invention, an inverse of the second signal is the third signal delayed by a delay time.

In another embodiment, a control method adapted to drive a power conversion circuit is provided. The power conversion circuit comprises a high-side transistor and a low-side transistor. The low-side transistor is deposited in an isolation layer. The control method comprises the following steps. The high-side transistor is driven by a first signal. The low-side transistor is driven by a second signal. Before driving the low-side transistor, the isolation layer is biased by a third signal to reduce reverse recovery charge of the low-side transistor. The third signal is an inverse of the second signal.

According to an embodiment of the present invention, the inverse of the second signal is the third signal delayed by a delay time.

According to an embodiment of the present invention, before the second signal reaches a low voltage level to turn off the low-side transistor, the third signal reaches a high voltage level. Before the second signal reaches the high voltage level to turn on the low-side transistor, the third signal reaches the low voltage level.

According to an embodiment of the present invention, the low-side transistor is an N-type laterally diffused metal oxide semiconductor. The high-side transistor is the N-type laterally diffused metal oxide semiconductor.

According to an embodiment of the present invention, the isolation layer is deposited on a P-type substrate.

According to an embodiment of the present invention, the power conversion circuit is a synchronous buck converter.

According to an embodiment of the present invention, after the high-side transistor is turned off and before the low-side transistor is turned on, there is a dead time.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic diagram showing a synchronous buck converter;

FIG. 2 is a circuit diagram showing a power conversion circuit in accordance with an embodiment of the present invention;

FIG. 3 is a waveform diagram showing a power conversion circuit in accordance with an embodiment of the present invention;

FIG. 4 is a cross-sectional view of a transistor in accordance with an embodiment of the present invention; and

FIG. 5 is a flow chart showing a control method in accordance with an embodiment of the present invention.

### DETAILED DESCRIPTION OF THE INVENTION

The following description is made for the purpose of illustrating the general principles of the disclosure and should not be taken in a limiting sense. The scope of the disclosure is determined by reference to the appended claims.

In the following detailed description, for purposes of explanation, numerous specific details and embodiments are set forth in order to provide a thorough understanding of the present disclosure. The use of like and/or corresponding numerals in the drawings of different embodiments does not suggest any correlation between different embodiments.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In addition, in this specification, relative spatial expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer or section. Thus, a first element, component, region, layer, portion or section in the specification could be termed a second element, component, region, layer, portion or section in the claims without departing from the teachings of the present disclosure.

It should be understood that this description of the exemplary embodiments is intended to be read in connection with the accompanying drawings, which are to be considered part of the entire written description. The drawings are not drawn to scale. In addition, structures and devices are shown schematically in order to simplify the drawing.

The terms “approximately”, “about” and “substantially” typically mean a value is within a range of +/−20% of the stated value, more typically a range of +/−10%, +/−5%, +/−3%, +/−2%, +/−1% or +/−0.5% of the stated value. The stated value of the present disclosure is an approximate value. Even there is no specific description, the stated value still includes the meaning of “approximately”, “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In the drawings, similar elements and/or features may have the same reference number. Various components of the same type can be distinguished by adding letters or numbers after the component symbol to distinguish similar components and/or similar features.

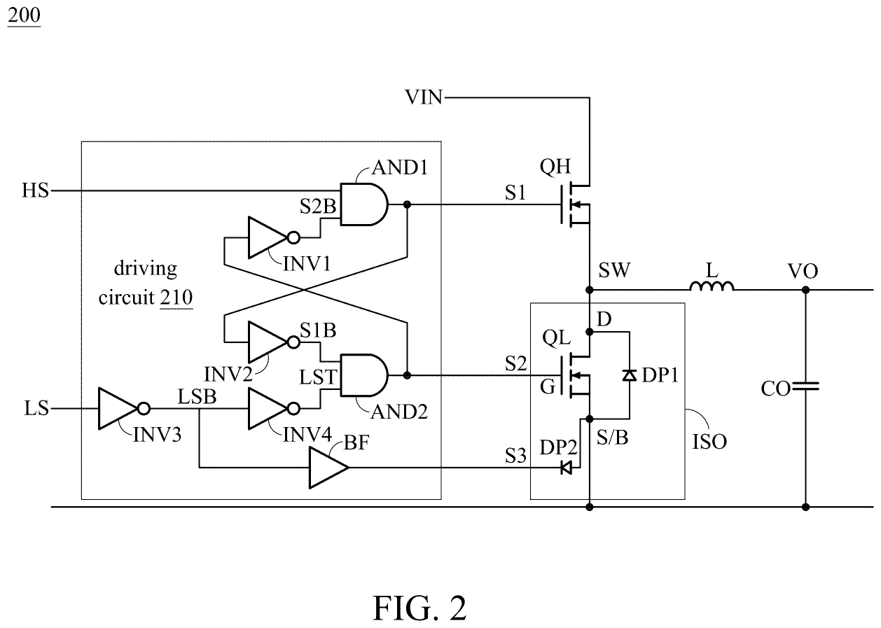

FIG. 2 is a circuit diagram showing a power conversion circuit in accordance with an embodiment of the present invention. As shown in FIG. 2, the power conversion circuit 200 includes a high-side transistor QH, a low-side transistor QL, an inductor L, an output capacitor CO, and a driving circuit 210. According to an embodiment of the present invention, the power conversion circuit 200 may be a synchronous buck converter. According to other embodiments of the present invention, the power conversion circuit 200 may be any switching power conversion circuit. A synchronous buck converter is merely illustrated herein for explanation and description, and the present invention is not intended to be limited thereto.

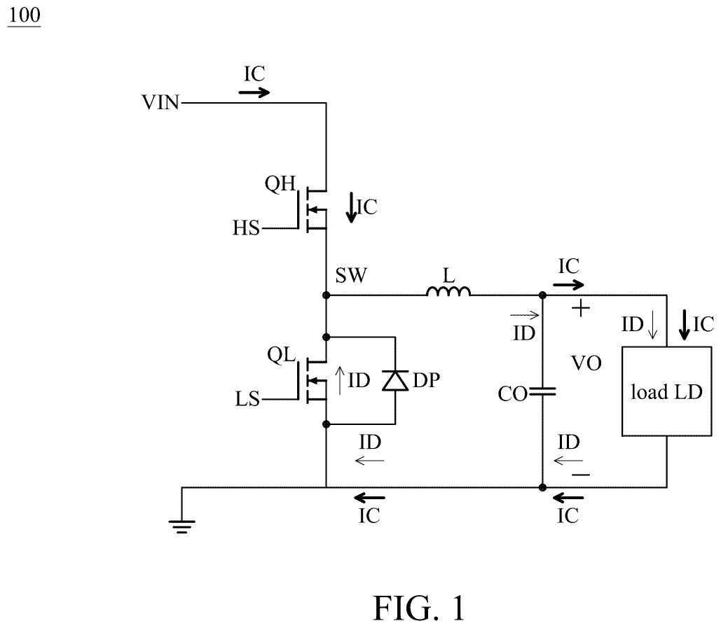

Comparing the power conversion circuit 200 with the power conversion circuit 100 of FIG. 1, the low-side transistor QL of the power conversion circuit 200 is deposited in the isolation layer ISO and includes a first parasitic diode DP1 and a second parasitic diode DP2. As shown in FIG. 2, the low-side transistor QL includes a gate terminal G, a drain terminal D, a source terminal S, and a base terminal B, where the base terminal B and the source terminal S are coupled to each other, a first parasitic diode DP1 is formed from the base terminal B to the drain terminal D, and a second parasitic diode DP2 is formed from the base terminal B to the isolation layer ISO.

According to one embodiment of the present invention, the low-side transistor QL can be a laterally diffused metal oxide semiconductor (LDMOS). In the embodiment of FIG. 2, the low-side transistor QL is an N-type laterally diffused metal oxide semiconductor. According to other embodiments of the present invention, the high-side transistor QH may be a lateral diffused metal oxide semiconductor, or may be an N-type lateral diffused metal oxide semiconductor or a P-type lateral diffused metal oxide semiconductor. For the convenience of explanation, the low-side transistor QL is only illustrated as an N-type laterally diffused metal oxide semiconductor, and is not intended to be limited thereto.

As shown in FIG. 2, the driving circuit 210 generates a first signal S1, the second signal S2, and a third signal S3 based on the high-side driving signal HS and the low-side driving signal LS, and includes a first inverter INV1, a first AND gate AND1, a second inverter INV2, and a second AND gate AND2, a third inverter INV3, a buffer BF, and a fourth inverter INV4.

According to an embodiment of the present invention, when the first signal S1 and the second signal S2 are both in a disabled state and the high-side driving signal HS is in the enabled state, the first inverter INV1 inverts the disabled second signal S2 to generate an enabled second inverted signal S2B. The first AND gate AND1 performs a logic AND operation on the enabled high-side driving signal HS and the enabled second inverted signal S2B to generate an enabled first signal S1, so that the high-side transistor QH is turned on based on the enabled first signal S1.

According to another embodiment of the present invention, when the high-side driving signal HS is in a disabled state and the low-side driving signal LS is in a disabled state (i.e., the low voltage level), the first signal S1 is in a disabled state, and the third inverter INV3 inverts the disabled low-side driving signal LS to generate an enabled inverted low-side signal LSB. The buffer BF generates an enabled third signal S3 by using the enabled inverted low-side signal LSB, and provides the third signal S3 to the isolation layer ISO of the low-side transistor QL. In other words, when the low-side driving signal LS is in a disabled state, the voltage provided to the isolation layer ISO is at the high voltage level, and the inverted low-side signal LSB and the third signal S3 are in phase. According to an embodiment of the present invention, there is a dead time after the high-side transistor QH is turned off and before the low-side transistor QL is turned on.

Next, the second inverter INV2 inverts the disabled first signal S1 to generate an enabled first inverted signal S1B. The fourth inverter INV4 inverts the enabled inverted low-side signal LSB to generate the disabled low-side trigger signal LST. The second AND gate AND2 performs a logic AND operation on the enabled first inverted signal S1B and the disabled low-side trigger signal LST to generate a disabled second signal S2 to turn off the low-side transistor QL.

According to another embodiment of the present invention, when the high-side driving signal HS is in a disabled state and the low-side driving signal LS is in an enabled state (i.e., the high voltage level), the third inverter INV3 inverts the low-side driving signal LS to generate a disabled inverted low-side signal LSB. The buffer BF generates a disabled third signal S3 by utilizing the disabled inverted low-side signal LSB, and provides the third signal S3 to the isolation layer ISO of the low-side transistor QL. In other words, when the low-side driving signal LS is in an enabled state, the voltage provided to the isolation layer ISO is at the low voltage level.

In addition, the fourth inverter INV4 inverts the disabled inverted low-side signal LSB to generate the enabled low-side trigger signal LST. The second AND gate AND2 performs a logic AND operation on the enabled first inverted signal S1B and the enabled low-side trigger signal LST to generate an enabled second signal S2 to turn on the low-side transistor QL.

According to some embodiments of the present invention, the first inverter INV1, the first AND gate AND1, the second inverter INV2, and the second AND gate AND2 are configured to generate the first signal S1 and the second signal S2 which are inverted from each other to avoid the high-side transistor QH and the low-side transistor QL being turned on at the same time to cause power loss.

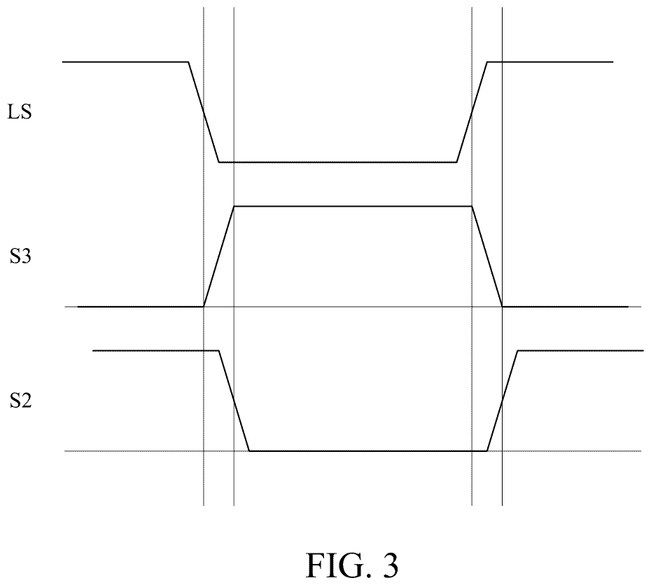

FIG. 3 is a waveform diagram showing a power conversion circuit in accordance with an embodiment of the present invention. The following description of the waveform diagram 300 of FIG. 3 will be explained in detail with reference to the power conversion circuit 200 of FIG. 2.

As shown in FIG. 3, when the low-side driving signal LS is converted from the high voltage level to the low voltage level, the driving circuit 210 first generates a third signal S3 at the high voltage level to the isolation layer ISO, and then generates the second signal S2 at the low voltage level to turn off the low-side transistor QL. When the low-side driving signal LS is converted from the low voltage level to the high voltage level, the driving circuit 210 first generates the third signal S3 at the low voltage level to the isolation layer ISO, and then generates the second signal S2 at the high voltage level to turn on the low-side transistor QL. In other words, the inverse of the second signal S2 delayed by a delay time is equivalent to the third signal S3, and the second inverted signal S2B is delayed by a delay time of the first inverter INV1 compared to the inverse of the second signal S2. Therefore, the second inverted signal S2B is different from the inverse of the second signal S2.

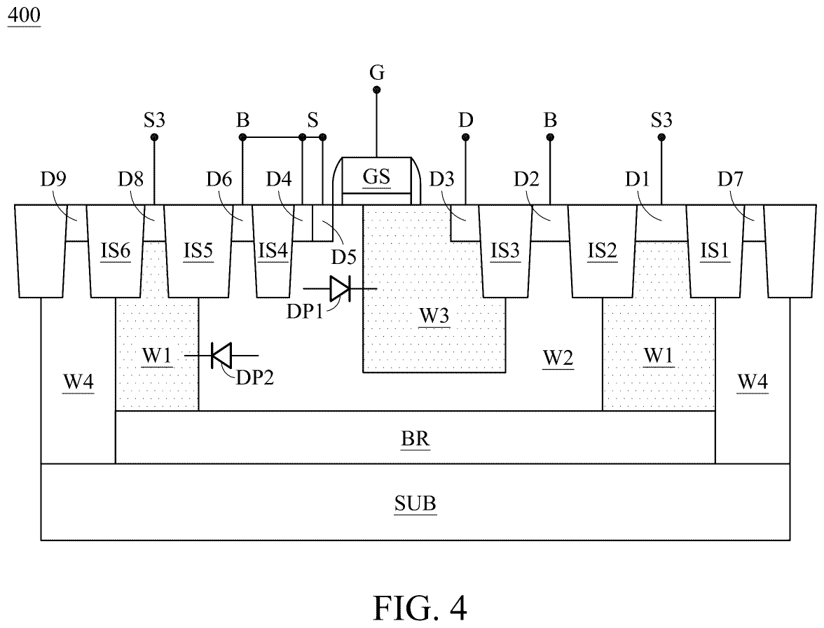

FIG. 4 is a cross-sectional view of a transistor in accordance with an embodiment of the present invention. The transistor 400 includes a semiconductor substrate SUB, a barrier layer BR, a first well W1, a second well W2, a third well W3, and a fourth well W4.

The semiconductor substrate SUB has a first conductivity type. According to an embodiment of the present invention, the semiconductor substrate SUB is a silicon substrate. According to other embodiments of the present invention, the semiconductor substrate SUB may also be a lightly doped semiconductor substrate having the first conductivity type.

The barrier layer BR is deposited in the semiconductor substrate SUB and has a second conductivity type. According to an embodiment of the present invention, the first conductivity type is P-type, and the second conductivity type is N-type. According to an embodiment of the present invention, the barrier layer BR may be formed by an ion implantation step. For example, phosphorus ions or arsenic ions may be implanted in the region predetermined to form the barrier layer BR, so as to form the barrier layer BR.

The first well W1 is formed on the barrier layer BR, in contact with the barrier layer BR, and it has the second conductivity type. According to an embodiment of the present invention, the first well W1 may be formed by an ion implantation step. For example, phosphorus ions or arsenic ions may be implanted in a region predetermined to form the first well W1, so as to form the first well W1.

The second well W2 is deposited in the first well W1, located on the barrier BR, and has the first conductivity type. According to an embodiment of the present invention, the second well W2 may be formed by an ion implantation step. For example, boron ions or indium ions may be implanted in the region predetermined to form the second well W2, so as to form the second well W2. According to an embodiment of the present invention, the doping concentration of the second well W2 is higher than the doping concentration of the semiconductor substrate SUB.

The third well W3 is deposited in the second well W2 and has the second conductivity type. According to an embodiment of the present invention, the third well W3 may be formed by an ion implantation step. For example, phosphorus ions or arsenic ions may be implanted in the region predetermined to form the third well W3, so as to form the third well W3.

The fourth well W4 is deposited in the semiconductor substrate SUB, surrounds the first well W1, and has the first conductivity type. According to an embodiment of the present invention, the fourth well W4 may be formed by an ion implantation step. For example, boron ions or indium ions may be implanted in the region predetermined to form the fourth well W4, so as to form the fourth well W4. According to an embodiment of the present invention, the doping concentration of the fourth well W4 is higher than the doping concentration of the semiconductor substrate SUB. According to another embodiment of the present invention, the doping concentration of the fourth well W4 may be equal to the doping concentration of the semiconductor substrate SUB.

According to some embodiments of the present invention, the first conductivity type and the second conductivity type are different. In other words, the barrier layer BR, the first well W1, and the third well W3 have the same conductivity type, and the semiconductor substrate SUB and the second well W2 have the same conductivity type.

As shown in FIG. 4, the transistor 400 further includes a first doping region D1, a second doping region D2, a third doping region D3, a fourth doping region D4, a fifth doping region D5, a sixth doping region D6, a seventh doping region D7, an eighth doping region D8, and a ninth doping region D9. The first doped region D1 is deposited in the first well W1 and has the second conductivity type. According to an embodiment of the present invention, the doping concentration of the first doping region D1 is higher than the doping concentration of the first well W1, and also higher than the doping concentration of the barrier layer BR.

The second doped region D2 is deposited in the second well W2 and has the first conductivity type. According to an embodiment of the present invention, the doping concentration of the second doping region D2 is higher than the doping concentration of the second well W2. The third doped region D3 is deposited in the third well W3 and has the second conductivity type. According to an embodiment of the present invention, the doping concentration of the third doping region D3 is higher than the doping concentration of the third well W3.

The fourth doped region D4 is deposited in the second well W2 and has the first conductivity type. According to an embodiment of the present invention, the doping concentration of the fourth doping region D4 is higher than the doping concentration of the second well W2. The fifth doping region D5 is deposited in the second well W2, located between the third doping region D3 and the fourth doping region D4, and has the second conductivity type. The sixth doped region D6 is deposited in the second well W2 and has the first conductivity type. According to an embodiment of the present invention, the doping concentration of the sixth doping region D5 is higher than the doping concentration of the second well W2.

The seventh doped region D7 is deposited in the fourth well W4 and has the first conductivity type. According to an embodiment of the present invention, the doping concentration of the seventh doping region D7 is higher than the doping concentration of the fourth well W4. The eighth doped region D8 is deposited in the first well W1 and has the second conductivity type. According to an embodiment of the present invention, the doping concentration of the eighth doping region D8 is higher than the doping concentration of the first well W1. The ninth doped region D9 is deposited in the fourth well W4 and has the first conductivity type. According to an embodiment of the present invention, the doping concentration of the ninth doping region D9 is higher than the doping concentration of the fourth well W4.

As shown in FIG. 4, transistor 400 further includes a gate structure GS. The gate structure GS is deposited on the second well W2 and the third well W3, and is located between the third doping region D3 and the fifth doping region D5.

As shown in FIG. 4, the transistor 400 further includes a first isolation structure IS1, a second isolation structure IS2, a third isolation structure IS3, a fourth isolation structure IS4, a fifth isolation structure IS5, and a sixth isolation structure IS6. The first isolation structure ISO1 is located between the first doping region D1 and the seventh doping region D7 for separating the first doping region D1 from the seventh doping region D7. As shown in FIG. 4, the first isolation structure IS1 directly contacts the first doping region D1 and the seventh doping region D7, but this is not intended to limit the present invention. According to other embodiments of the present invention, the first isolation structure IS1 does not contact at least one of the first doping region D1 and the seventh doping region D7.

The second isolation structure IS2 is located between the first doping region D1 and the second doping region D2 to separate the first doping region D1 from the second doping region D2. As shown in FIG. 4, the second isolation structure IS2 directly contacts the first doped region D1 and the second doped region D2, but this is not intended to limit the present invention. According to other embodiments of the present invention, the second isolation structure IS2 does not contact at least one of the first doping region D1 and the second doping region D2.

The third isolation structure IS3 is located between the second doping region D2 and the third doping region D3 to separate the second doping region D2 from the third doping region D3. As shown in FIG. 4, the third isolation structure IS3 directly contacts the second doping region D2 and the third doping region D3, but this is not intended to limit the present invention. According to other embodiments of the present invention, the third isolation structure IS3 does not contact at least one of the second doping region D2 and the third doping region D3.

The fourth isolation structure IS4 is located between the fourth doping region D4 and the sixth doping region D6 to separate the fourth doping region D4 from the sixth doping region D6. As shown in FIG. 4, the fourth isolation structure IS4 directly contacts the fourth doping region D4 and the sixth doping region D6, but this is not intended to limit the present invention. According to other embodiments of the present invention, the fourth isolation structure IS4 does not contact at least one of the fourth doping region D4 and the sixth doping region D6.

The fifth isolation structure IS5 is located between the sixth doping region D6 and the eighth doping region D8 to separate the sixth doping region D6 from the eighth doping region D8. As shown in FIG. 4, the fifth isolation structure IS5 directly contacts the sixth doping region D6 and the eighth doping region D8, but this is not intended to limit the present invention. According to other embodiments of the present invention, the fifth isolation structure IS5 does not contact at least one of the sixth doping region D6 and the eighth doping region D8.

The sixth isolation structure IS6 is located between the eighth doping region D8 and the ninth doping region D9 to separate the eighth doping region D8 from the ninth doping region D9. As shown in FIG. 4, the sixth isolation structure IS6 directly contacts the eighth doping region D8 and the ninth doping region D9, but this is not intended to limit the present invention. According to other embodiments of the present invention, the sixth isolation structure IS6 does not contact at least one of the eighth doping region D8 and the ninth doping region D9.

According to some embodiments of the present invention, the gate-collector structure GS forms the gate terminal G of the low-side transistor QL in FIG. 2, the second doping region D2 and the sixth doping region D6 form the base terminal B of the low-side transistor QL, the third doping region D3 forms the drain terminal D of the low-side transistor QL, and the fourth doping region D4 and the fifth doping region D5 form the source terminal S of the low-side transistor QL. In addition, the fourth doping region D4, the fifth doping region D5, and the sixth doping region D6 are electrically connected together.

According to some embodiments of the present invention, the first well W1 and the barrier layer BR form the isolation layer ISO of the low-side transistor QL in FIG. 2, and the first doped region D1 and the eighth doped region D8 are configured to receive the third signal S3 in FIG. 3. In addition, the seventh doping region D7 and the ninth doping region D9 are configured to receive the lowest voltage level of the power conversion circuit 200 of FIG. 2.

According to some embodiments of the present invention, the interface between the second well W2 and the third well W3 forms the first parasitic diode DP1 of the low-side transistor QL in FIG. 2, and the interface between the first well W1 and the second well W2 and the interface between the barrier layer BR and the second well W2 form the second parasitic diode DP2 of the low-side transistor QL.

According to some embodiments of the present invention, when the transistor 400 is turned on, the reverse bias of the second parasitic diode DP2 increases the on-resistance between the drain terminal D (i.e., the third doping region D3) and the source terminal S (i.e., the fourth doping region D4 and the fifth doping region D5). In other words, when the transistor 400 (i.e., the low-side transistor QL) is turned on, the third signal S3 being at the low voltage level helps to reduce the on-resistance of the transistor 400 (i.e., the low-side transistor QL).

According to other embodiments of the present invention, when the transistor 400 is turned off, the reverse bias of the second parasitic diode DP2 helps to reduce the accumulation of minority carriers in the second well W2 and the third well W3, thereby reducing the reverse recovery charge. In other words, when the transistor 400 (i.e., the low-side transistor QL) is turned off, the third signal S3 is at the high voltage level, which helps to reduce the minority carriers in the second well W2 and the third well W3 that need to be eliminated, thereby reducing the reverse recovery charge of the transistor 400 (i.e., the low-side transistor QL) to shorten the reverse recovery time and to improve the conversion efficiency of the power conversion circuit 200.

According to one embodiment of the present invention, transistor 400 is an N-type laterally diffused metal oxide semiconductor. According to some embodiments of the present invention, the high-side transistor QH in FIG. 2 may be implemented the transistor 400 as well.

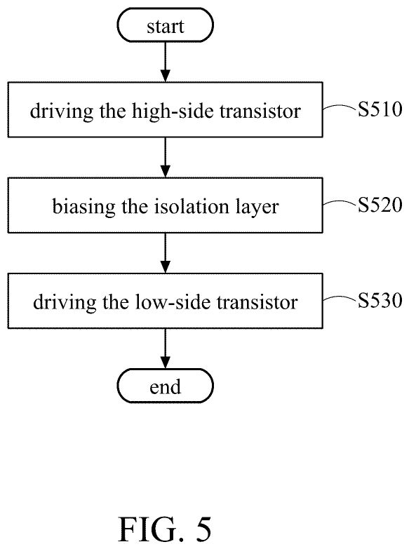

FIG. 5 is a flow chart showing a control method in accordance with an embodiment of the present invention. The following description of the flow chart 500 will be described in detail with reference to the power conversion circuit 200 of FIG. 2.

First, the first signal S1 is configured to drive the high bridge transistor QH (Step S510). Next, the isolation layer ISO is biased using the third signal S3 (Step S520). Finally, the second signal S2 is configured to drive the low-side transistor QL (Step S530). According to an embodiment of the present invention, before turning on the low-side transistor QL, the isolation layer ISO is biased at the low voltage level to reduce the on-resistance of the low-side transistor QL. According to another embodiment of the present invention, before turning off the low-side transistor QL, the isolation layer ISO is biased at the high voltage level to reduce the reverse recovery charge.

The present invention proposes a power conversion circuit and a control method for reducing reverse recovery charge. The reverse recovery charge is reduced by placing a switch element in an isolation layer and reverse biasing a parasitic diode formed by the isolation layer before the switching element is turned off. In addition, the biasing of the isolation layer is stopped before the switch element is turned on to reduce the on-resistance of the switch element.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A power conversion circuit, comprising:
a high-side transistor, providing an input voltage to a switch node based on a first signal;
a low-side transistor, coupling the switch node to a ground based on a second signal and deposited in an isolation layer; and
a driving circuit, generating the first signal, the second signal, and a third signal;
wherein the driving circuit provides the third signal to the isolation layer;
wherein the driving circuit generates the third signal based on the first signal and the second signal.

2. The power conversion circuit as claimed in claim 1, wherein before the low-side transistor is turned on, the driving circuit outputs the third signal at a low voltage level.

3. The power conversion circuit as claimed in claim 1, wherein before the low-side transistor is turned off, the driving circuit outputs the third signal at a high voltage level to reduce reverse recovery charge of the low-side transistor.

4. The power conversion circuit as claimed in claim 1, wherein the low-side transistor is an N-type laterally diffused metal oxide semiconductor.

5. The power conversion circuit as claimed in claim 1, wherein the high-side transistor is an N-type laterally diffused metal oxide semiconductor.

6. The power conversion circuit as claimed in claim 1, wherein the power conversion circuit is a synchronous buck converter.

7. The power conversion circuit as claimed in claim 1, wherein the low-side transistor comprises:
a semiconductor substrate, having a first conductivity type;
a barrier layer, having a second conductivity type and deposited on the semiconductor substrate;
a first well, having the second conductivity type, deposited on the barrier layer, and in contact with the barrier layer;
a second well, having the first conductivity type and deposited in the first well;
a third well, having the second conductivity type and deposited in the second well;
a first doping region, having the second conductivity type and deposited in the first well;
a second doping region, having the first conductivity type and deposited in the second well;
a third doping region, having the second conductivity type and deposited in the third well;
a fourth doping region, having the first conductivity type and deposited in the second well;
a fifth doping region, having the second conductivity type, deposited in the second well, and in contact with the fourth doping region; and
a gate structure, deposited on the second well and the third well and deposited between the fifth doping region and the third doping region;
wherein the barrier layer and the first well form the isolation layer;
wherein the first conductivity type and the second conductivity type are different.

8. The power conversion circuit as claimed in claim 7, wherein the low-side transistor comprises a gate terminal, a source terminal, a drain terminal, and a base terminal;
wherein the gate structure forms the gate terminal;
wherein the fourth doping region and the fifth doping region form the source terminal;
wherein the second doping region forms the drain terminal.

9. The power conversion circuit as claimed in claim 8, wherein the low-side transistor comprises:
a fourth well, having the first conductivity type, surrounding the first well, and in contact with the semiconductor substrate;
a sixth doping region, having the first conductivity type and deposited in the second well;
a seventh doping region, having the first conductivity type and deposited in the fourth well;
a first isolation structure, deposited between the first doping region and the seventh doping region;
a second isolation structure, deposited between the first doping region and the second doping region;
a third isolation structure, deposited between the second doping region and the third doping region; and
a fourth isolation structure, deposited between the fourth doping region and the sixth doping region;
wherein the sixth doping region forms the base terminal.

10. The power conversion circuit as claimed in claim 8, wherein the first doping region receives the third signal.

11. The power conversion circuit as claimed in claim 8, wherein when the first doping region receives the third signal being at a high voltage level and the low-side transistor is turned off, an interface between the first well and the second well and an interface between the barrier layer and the second well are reverse-biased, so as to reduce the minority carriers in the second well that need to be eliminated, thereby reducing reverse recovery charge.

12. The power conversion circuit as claimed in claim 8, wherein when the first doping region receives the third signal being at a low voltage level and the low-side transistor is turned on, the low-side transistor has low on-resistance.

13. The power conversion circuit as claimed in claim 1, wherein an inverse of the second signal is the third signal delayed by a delay time.

14. A control method adapted to drive a power conversion circuit, wherein the power conversion circuit comprises a high-side transistor and a low-side transistor, wherein the low-side transistor is deposited in an isolation layer, wherein the control method comprises the following steps:
driving the high-side transistor by a first signal;
driving the low-side transistor by a second signal; and
before driving the low-side transistor, biasing the isolation layer by a third signal to reduce reverse recovery charge of the low-side transistor;
wherein the third signal is an inverse of the second signal.

15. The control method as claimed in claim 14, wherein the inverse of the second signal is the third signal delayed by a delay time.

16. The control method as claimed in claim 14, wherein before the second signal reaches a low voltage level to turn off the low-side transistor, the third signal reaches a high voltage level;
wherein before the second signal reaches the high voltage level to turn on the low-side transistor, the third signal reaches the low voltage level.

17. The control method as claimed in claim 14, wherein the low-side transistor is an N-type laterally diffused metal oxide semiconductor;
wherein the high-side transistor is the N-type laterally diffused metal oxide semiconductor.

18. The control method as claimed in claim 14, wherein the isolation layer is deposited on a P-type substrate.

19. The control method as claimed in claim 14, wherein the power conversion circuit is a synchronous buck converter.

20. The control method as claimed in claim 14, wherein after the high-side transistor is turned off and before the low-side transistor is turned on, there is a dead time.
